(19) United States
(12) Patent Application Publication
(10) Pub. No.: US 2006/0157796 A1
(43) Pub. Date: Jul. 20, 2006

(54) Semiconductor device having dual gate electrode and related method of formation

(76) Inventors: Min-Joo Kim, Anyang-si (KR); Jong-Ho Lee, Suwon-si (KR); Sung-Kee Han, Seongnam-si (KR); Hyung-Suk Jung, Suwon-si (KR)

Correspondence Address: VOLENTINE FRANCOS, & WHITT PLLC, ONE FREEDOM SQUARE, 11951 FREEDOM DRIVE SUITE 1260, RESTON, VA, 20190, US

(21) Appl. No.: 11/312,806

(22) Filed: Dec. 21, 2005

(30) Foreign Application Priority Data
Jan. 14, 2005 (KR) 2005-03844

(51) Int. Cl. H01L 29/78; H01L 21/4763

(52) U.S. Cl. 257/369; 257/412; 438/199; 438/592

(57) ABSTRACT

A dual gate electrode semiconductor device and related method of formation are disclosed. The semiconductor device comprises a first gate electrode made of a metal silicide layer and a second gate electrode made of a metal layer, wherein the metal suicide is formed from the same metal as the metal layer.

### BACKGROUND OF THE INVENTION

1. Field of the Invention

Embodiments of the invention relate to a semiconductor device and a related method of formation. More particularly, embodiments of the invention relate to a semiconductor device having a dual gate electrode and a related method of formation.

This application claims the benefit of Korean Patent Application No. 2005-03844 filed Jan. 14, 2005, the subject matter of which is hereby incorporated by reference in its entirety.

2. Description of the Related Art

Generally, a complementary metal oxide silicon (CMOS) semiconductor device includes an n-channel metal oxide silicon (NMOS) transistor forming one channel type accumulating electrons, and a p-channel metal oxide silicon (PMOS) transistor forming another channel type accumulating holes.

In order to improve productivity by simplifying the fabrication method for the CMOS semiconductor device, N-type polysilicon has been used to form both of the NMOS gate electrode and the PMOS gate electrode within these two structures. As a result, a surface channel is formed in NMOS transistor structure and a buried channel is formed in the PMOS transistor structure due to the work function of the N-type polysilicon. However, the threshold voltage of the PMOS transistor having a buried channel may increase, thereby decreasing the operating speed of the PMOS transistor. This result is increasingly detrimental as CMOS semiconductor devices face demands for increasing operating speed. Therefore, a PMOS transistor having a surface channel has become a highly desirable design objective.

In order to address this design objective, one conventional method of forming both NMOS transistor and PMOS transistors having respective surface channels has been proposed. In this conventional method, N-type polysilicon is used to form an NMOS gate electrode, and P-type polysilicon is used to form a PMOS gate electrode. Since the work function of the PMOS gate electrode is similar to a valance band of silicon, a PMOS transistor is provided with a surface channel.

However, the operating speed of the respective transistors may nonetheless decrease because of the high resistance of the doped polysilicon when the N-type impurities and the P-type impurities are used to form the NMOS gate electrode and the PMOS gate electrode. Also, the thickness of the constituent gate oxide layer may necessarily become thicker because a depletion region is formed in the NMOS and PMOS gate electrodes. As a result, the absolute values of threshold voltages for the PMOS and the NMOS transistors may actually increase, thereby reducing operating speed for the NMOS and PMOS transistors.

In order to overcome this drawback, a metal layer has been used to form both the NMOS and PMOS gate electrodes. The metal layer has a work function which is similar to an intermediate value of silicon's energy band gap. With this structure, the absolute value of the threshold voltage for the PMOS transistor may decrease. However, the absolute value of threshold voltage for the NMOS transistor may increase. That is, it is very difficult to decrease the threshold voltages for both the NMOS and PMOS transistors.

### SUMMARY OF THE INVENTION

Embodiments of the invention provide a semiconductor device having a dual gate electrode providing improved performance characteristics, such as for example, threshold voltage, work function, etc., for both the NMOS and PMOS transistors, as well and a related method of formation.

In one embodiment, the invention provides a semiconductor device comprising; a first gate electrode formed on a first region of a semiconductor substrate and comprising a metal silicide formed from a metal, and a second gate electrode formed on a second region of the semiconductor substrate and comprising the metal.

In another embodiment, the invention provides a method of forming a semiconductor device, comprising; forming an insulating layer on a semiconductor substrate and forming a semiconductor layer on the insulating layer, wherein the semiconductor substrate comprises first and second regions, exposing a portion of the insulating layer by removing a portion of the semiconductor layer on the second region, after exposing the portion of the insulating layer, depositing a metal layer on the first and second regions of the semiconductor substrate, forming a metal silicide layer from a remaining portion of the semiconductor layer and a portion of the metal layer formed on the first region using a silicidation process, forming a first gate electrode from the metal silicide layer on the first region, and forming a second gate electrode from the metal layer on the second region.

### BRIEF DESCRIPTION OF THE DRAWINGS

Embodiments of the invention are described in relation to the accompanying drawings, in which:

FIG. 1 is a cross-sectional view of a semiconductor device having a dual gate electrode according to one embodiment of the invention; and

FIGS. 2 through 6 are cross-sectional views for explaining a method of forming a semiconductor device having a dual gate electrode according to an embodiment of the present invention.

### DESCRIPTION OF EXEMPLARY EMBODIMENTS

Reference will now be made in some additional detail to exemplary embodiments of the invention, examples of which are illustrated in the accompanying drawings. However, the invention is not limited to only the embodiments described herein.

FIG. 1 is a cross-sectional view of a semiconductor device having a dual gate electrode according to one embodiment of the invention.

Referring to FIG. 1, a semiconductor substrate 100 comprises a first region “a” and a second region “b”. One of the first region “a” and the second region “b” is an NMOS region where an NMOS transistor is formed and the other is a PMOS region where a PMOS transistor is formed.

A first gate pattern 120a is formed on the first region of semiconductor substrate 100, and a second gate pattern 120b is formed on the second region of semiconductor substrate 100. A device isolation layer (not shown) may also be formed in a predetermined region of semiconductor substrate 100 to define a first active region in the first region “a” and a second active region in the second region “b”. The first gate pattern 120a and the second gate pattern 120b are formed on the first active region and the second active region, respectively. The term “on” in this context may mean directly on or on through intervening layers, elements or regions. Thus, FIG. 1 is a cross-sectional view showing the first and second active regions of the exemplary CMOS semiconductor device.

A first spacer 124a may be disposed on side walls of the first gate pattern 120a, and a second spacer 124b may be disposed on side walls of the second gate pattern 120b. The first spacer 124a and the second spacer 124b may be formed from silicon oxide, a silicon nitride, and/or a silicon oxy-nitride layer as serves as an insulating region.

A first source/drain region 128a is formed on opposing sides of the first gate pattern 120a, and a second source/drain region 128b is formed on opposing sides of the second gate pattern 120b. The first source/drain region 128a is doped with first conductivity type impurities, and the second source/drain region 128b is doped with second conductivity type impurities. In the working example, therefore, the first region “a” of semiconductor substrate 100 is doped with second conductivity type impurities and the second region “b” of semiconductor substrate 100 is doped with first conductivity type impurities.

Generally, first conductivity type impurities differ from second conductivity type impurities. For example, the first conductivity type impurities may be N-type impurities and the second conductivity type impurities may be P-type impurities. Conversely, the first conductivity type impurities may be P-type impurities and the second conductivity type impurities may be N-type impurities. Accordingly, the first source/drain region 128a is coupled across a channel portion of the first region “a” of semiconductor substrate 100 as a first PN junction, and the second source/drain region 128b is coupled across a channel region of the second region “b” of semiconductor 100 as a second PN junction.

The first source/drain region 128a may be formed from a lightly doped drain (LDD) structure comprising a first low-concentration doping layer 122a and a first high-concentration doping layer 126a. Also, the first source/drain region 128a may be formed from an extended source/drain structure wherein the impurity concentration of the first low-concentration doping layer 122a is close to an impurity concentration of the first high-concentration doping layer 126a. Alternatively, the first source/drain region 128a may include only a single doping layer, such as the first low-concentration doping layer 122a.

The second source/drain region 128b may be formed in a manner similar to that described above in relation to the first source/drain region 128a.

The first gate pattern 120a includes a first gate insulating layer 102a, a first gate electrode 108a, a first capping conductivity pattern 112a and a first mask pattern 114a, which are stacked in sequence. The second gate pattern 120b includes a second gate insulating layer 102b, a second gate electrode 106a, a second capping conductivity pattern 112b and a second mask pattern 114b, which are stacked in sequence.

Each of the first gate insulating layer 102a and the second gate insulating layer 102b may be formed from one or more materials including a silicon oxide, a metal silicate having high dielectric constant, and a metal oxide having high dielectric constant, and/or a combination thereof. The metal silicate layer may be formed from hafnium silicate, zirconium silicate, tantalum silicate, titanium silicate, yttrium silicate, and/or aluminum silicate, and any reasonable combination thereof. The metal oxide layer may be formed from hafnium oxide, aluminum oxide, zirconium oxide, tantalum oxide, titanium oxide, and/or yttrium oxide, or any reasonable combination thereof.

The first gate electrode 108a may be formed from a metal silicide. In one embodiment, an impurity accumulation layer 110 is provided at a lower portion of the first gate electrode 108a. The impurity accumulation layer 110 modulates the work function of the lower portion of the first electrode 108a contact to the first gate insulating layer 102a. In the illustrated embodiment, it is preferable that the impurities of the impurity accumulation layer 110 be of similar type to those in the first source/drain region 128a.

The metal silicide layer of the first gate electrode 108a may include metal and/or silicon based materials. The metal silicide layer may, for example, further comprise germanium. The second gate electrode 106a may be formed from a metal layer. In one related embodiment, the first gate electrode 108a and the second gate electrode 106a are formed from the same type of material.

The first gate electrode 108a and the second gate electrode 106a have different work functions. That is, (e.g.,) the metal silicide layer of the first gate electrode 108a and the metal layer of the second gate electrode 106a have different work functions. The first gate electrode 108a may have a smaller work function than the second gate electrode 106a. On the contrary, the first gate electrode 108a may have a larger work function than the second gate electrode 106a.

In the exemplary embodiment illustrated in FIG. 1, the first region “a” is the NMOS region and the second region “b” is the PMOS region. In this case, the first gate electrode 108a has a smaller work function than the second gate electrode 106a. In one related aspect, it may be preferable in some embodiments that the work function of the first gate electrode 108a be close to a conduction band of silicon, and the work function of the second gate electrode 106a be close to a valence band of silicon. Thus, in the illustrated example, the first source/drain region 128a is doped with one or more N-type impurities, and the second source/drain region 128b is doped with one or more P-type impurities. The impurity accumulation layer 110 modulates the work function of the lower portion of the first gate electrode 108a as described above. As noted above, in one embodiment the impurity accumulation layer 110 accumulates N-type impurities.

In one embodiment wherein the first region “a” is the NMOS region and the second region “b” is the PMOS region, it is preferable that the first gate electrode 108a and the second gate electrode 106a comprise at least one material such as cobalt, nickel, platinum, and/or palladium. In other words, the first gate electrode 108a may be formed from one or more materials comprising cobalt silicide having a work function of about 4.36 eV, nickel silicide having a work function of about 4.6 eV, and/or palladium silicide having a work function of about 4.6 eV. (The unit “eV” indicates electron volts).

The first gate electrode 108a may further comprise germanium. That is, the first gate electrode 108a may alternately be formed of from one or materials comprising cobalt germanosilicide, nickel germanosilicide, platinum germanosilicide and/or palladium germanosilicide.

The second gate electrode 106a may be formed from one or similar materials, or identical metal materials used to form the first gate electrode 108a. That is, the second gate electrode 106a may be formed from cobalt having a work function of about 5.0 eV, nickel having a work function of about 5.22 eV, platinum having a work function of about 5.34 eV, and/or palladium having a work function of about 5.22 eV.

The work functions of materials such as cobalt, nickel, and platinum, as used to form the second gate electrode 106a, are close to the work function of silicon's valence band which is 5.0 eV. Therefore, the threshold voltage (and correspondingly the operating speed) of the PMOS transistor in the second region “b” is improved by the presence within the PMOS transistor of a surface channel.

In contrast, the work functions of cobalt silicide, nickel silicide, platinum silicide, and palladium silicide, as used to form the first gate electrode 108a, are relatively close to the work function of silicon's conduction band, at least by way of comparison to the second gate electrode 106a. Therefore, the threshold voltage of the NMOS transistor is also improved. This is particularly true where N-type impurities are effectively accumulated in the impurity accumulation layer 110. The impurity accumulation layer 110 decreases the work function of the lower portion of the first gate electrode 108a by as much as about 0.2 eV to about 0.4 eV. As a result, the work function of the lower portion of the first gate electrode 108a is further optimized to be close to the silicon's conduction band. Therefore, the threshold voltage of the NMOS transistor in the first region “a” is further improved.

An exemplary semiconductor device having a dual channel gate according to another embodiment of the invention will be described. In this embodiment, the first region “a” is the PMOS region and the second region “b” is the NMOS region. That is, the first gate electrode 108a has a larger work function than the second gate electrode 106a. In a related aspect to this embodiment, it is preferable that the work function of the first gate electrode 108a be close to the valence band of silicon, and the work function of the second gate electrode 106a be close to the conduction band of silicon. The first source/drain region 128a and the second source/drain region 128b are doped with one or more P-type impurities and one or more N-type impurities, respectively. Within the context of this exemplary structure, it is further preferable that the P-type impurities be accumulated in the impurity accumulation layer 110, which includes the same type of impurities as are included in the first source/drain region 128a.

When the first region “a” is the PMOS region and the second region “b” is the NMOS region, it is preferable that the first gate electrode 108a and the second gate electrode 106a be formed from a material such as molybdenum, tungsten, zirconium and/or tantalum. In one embodiment, the first gate electrode 108a and the second gate electrode 106a both comprise molybdenum.

In a more specific example, the first gate electrode 108a may be formed from one or more materials comprising molybdenum silicide having a work function of about 4.9 eV, tungsten silicide having a work function of about 4.8 eV, zirconium silicide having a work function of about 4.33 eV, and/or tantalum silicide having a work function of about 4.35 eV. Also, the first gate electrode 108a may be formed from one or more materials comprising molybdenum germanosilicide, tungsten germanosilicide, zirconium germanosilicide, and/or tantalum germanosilicide. The second gate electrode 106a may be formed from a metal layer identical to that used to form the first gate electrode 108a. That is, the second gate electrode 106a may be formed from one or more materials comprising molybdenum having a work function of about 4.2 eV, tungsten having a work function of about 4.63 eV, zirconium having a work function of about 4.05 eV, and/or tantalum having a work function of about 4.15 eV.

As described above, the work function of the first gate electrode 108a is relatively close to the silicon's valance band compared to the second gate electrode 106a, and the work function of the second electrode 106a is relatively close to the conduction band of silicon compared to the first gate electrode 108a. Accordingly, the PMOS transistor of the first region “a” and the NMOS transistor of the second region “b” have the improved threshold voltages. Therefore, the PMOS transistor and the NMOS transistor have better performance characteristics enabling higher speed operation.

In a further refinement of the foregoing example, the first gate electrode 108a may include the P-type impurity accumulation layer 110. In such, the impurity accumulation layer 110 increases the work function of the lower portion of the first gate electrode by as much as about 0.1 eV to about 0.3 eV. Therefore, the work function of the lower portion of the first gate electrode 108a is moved closer to the valance band of the silicon. As a result, the threshold voltage of the PMOS transistor formed in the first region “a” is further improved.

Referring to FIG. 1, the capping conductivity patterns 112a, 112b may be used to supplement the thickness of the gate patterns 120a, 120b when the thickness of the gate patterns 108a, 106a ranges from between about 10 angstrom or less to about 100 angstroms. The use of capping conductivity patterns 112a, 112b increase the operating speed of the transistors since the capping conductivity patterns 112a, 112b may be formed from a low resistance material such as metal. Furthermore, the capping conductivity patterns 112a, 112b protect the gate electrodes 108a and 106a. The first capping conductivity pattern 112a and the second capping conductivity pattern 112b have side walls arranged on the side walls of the first gate electrode 108a and the second gate electrode 106a. The first capping conductivity pattern 112a and the second capping conductivity pattern 112b may be formed from the same or different material(s). That is, the first capping conductivity pattern 112a and the second capping conductivity pattern 112b may be formed from a conductivity layer such as a doped polysilicon, as well as metals, such as tungsten or molybdenum, and/or a conductivity metal nitride such as titanium nitride and/or tantalum nitride.

However, the first capping conductivity layer 112a and the second capping conductivity layer 112b are optional to the illustrated embodiment and may be omitted at the designer's choice. In cases, the thickness of the first gate electrode 108a and the second gate electrode 106a may be increased to meet a thickness requirement for gate patterns 120a, 120b.

The first mask pattern 114a and the second mask pattern 114b of the first and second gate patterns 120a, 120b may be formed from an insulating layer such as silicon oxide, silicon nitride, and/or silicon oxy-nitride.

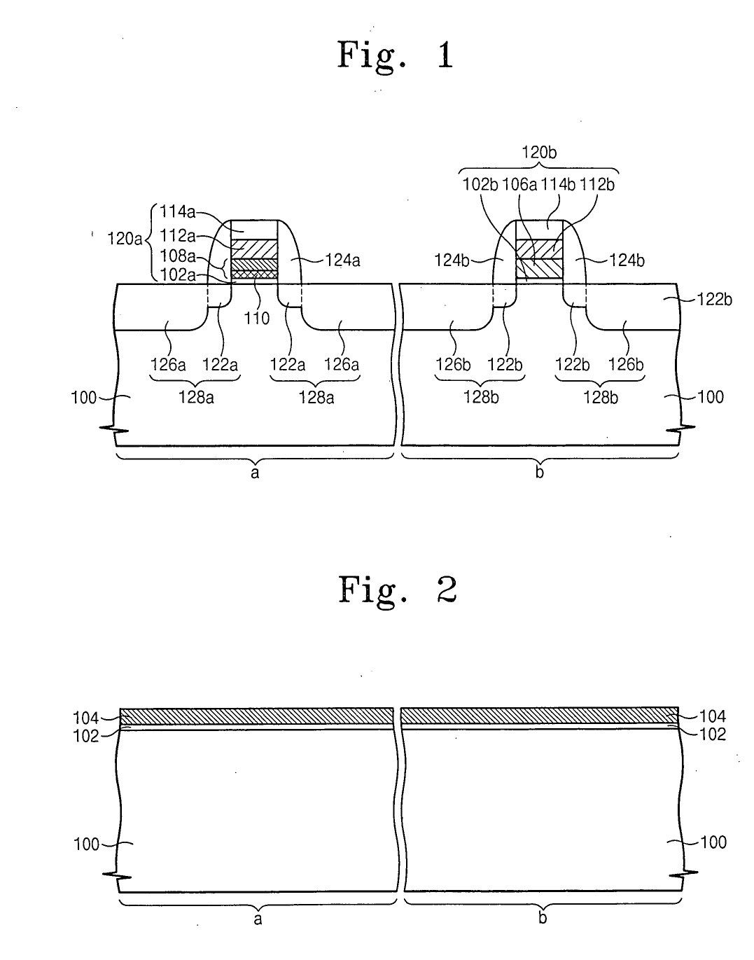

FIGS. 2 through 6 are cross-sectional views illustrating one exemplary method of forming a semiconductor device having a dual gate in accordance with one embodiment of the invention.

Referring to FIG. 2, a first region “a” and a second region “b” are formed in a semiconductor substrate 100. One of the first region “a” and the second region “b” is an NMOS region where the NMOS transistor is formed, and the other is a PMOS region where the PMOS transistor is formed.

A device isolation layer (not shown) may be formed at a predetermined region of the semiconductor substrate 100 to limit a first active region in the first region “a” and to limit a second active region in the second region “b”. Thus, FIGS. 2 through 6 show cross-sectional views taken along the respective active regions.

An insulating layer 102 and a semiconductor layer 104 are orderly formed on the semiconductor substrate 100. The insulating layer 102 may be formed from one or more materials selected from the group consisting of a silicon oxide, a silicon nitride, a metal silicate having high conductivity constant, and/or a metal oxide having high conductivity constant, and/or any reasonable combination thereof. The metal silicate layer and the metal oxide layer may be identical to the materials described with reference to FIG. 2.

The semiconductor layer 104 comprises a silicon material, and may (optionally) further comprise germanium. For example, the semiconductor layer 104 may be formed from polysilicon, amorphous silicon, and/or silicon germanium. Semiconductor layer 104 may further be doped with selected impurities. For example, an in-situ deposition method may be used to dope the semiconductor layer 104.

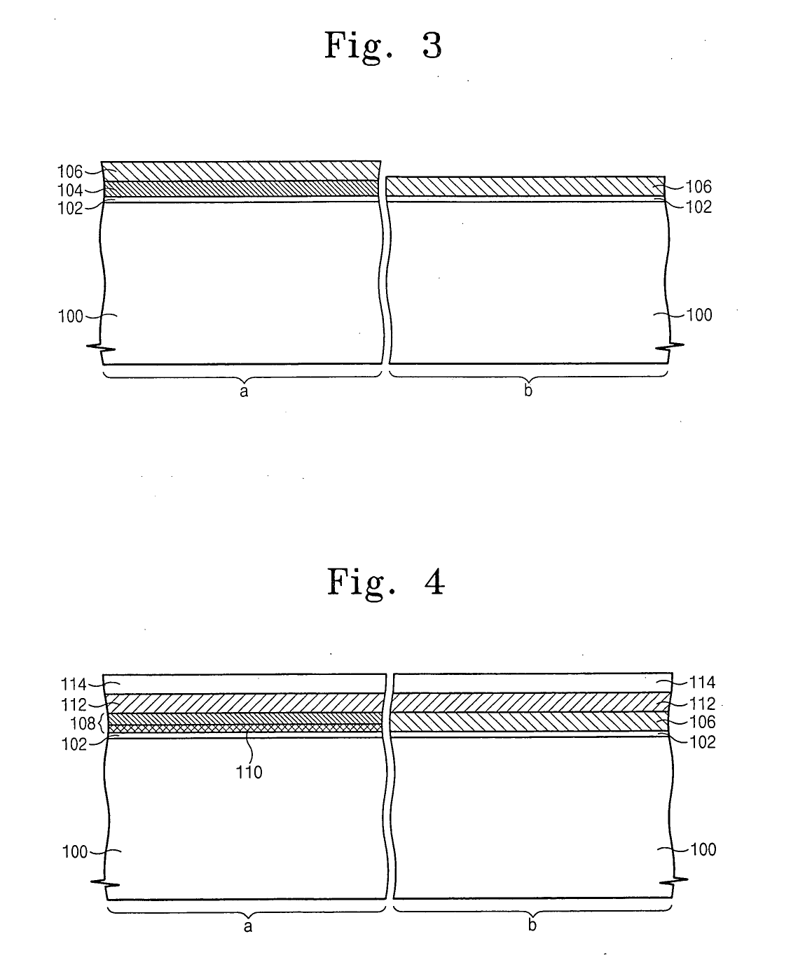

Referring to FIGS. 3 and 4, a portion of the semiconductor layer 104 on the second region “b” is removed to expose the insulating layer 102 of the second region “b”. However, the portion of semiconductor layer 104 of the first region “a” remains. The second conductor layer 104 of the second region “b” may be selectively removed using a conventional etching process such as one using a photosensitive pattern (not shown), or a conventional wet or dry etching process.

After selective removal of this portion of semiconductor layer 104, a metal layer 106 may be deposited on the semiconductor substrate 100. The metal layer 106 contacts the semiconductor layer 104 of the first region “a” and the insulating layer 102 of the second region “b”.

Then, a silicidation process is performed on the semiconductor substrate 100 having the metal layer 106. The silicidation process may comprise, for example, an annealing process reacting the metal layer 106 and the semiconductor layer 104 of the first region “a”. That is, a conventional silicidation process may be used to form a metal silicide layer 108 on the insulating layer 102 of the first region “a” by reacting the metal layer 106 and the semiconductor layer 104. The metal silicide layer 108 contacts the insulating layer 102 on the first region “a”. The metal silicide layer 108 comprises metal and silicon materials. Additionally, the metal silicide layer 108 may further comprise germanium.

When performing the silicidation process, the metal material contained in the metal layer 106 on the first region “a” is diffused into an upper surface of the semiconductor layer 104 and reacts with the semiconductor element forming the semiconductor layer 104. While reacting, the metal material forces the impurities within the semiconductor layer 104 downward towards the impurity accumulation layer 110 at a lower portion of the metal silicide layer 108. Un-reacted portions of the metal layer 106 may remain on the metal silicide layer 108.

The metal silicide layer 108 on the first region “a” has a different work function than the metal layer 106 on the second region “b”.

In the illustrated example, the first region “a” is the NMOS region and the second region “b” is the PMOS region. In this case, the metal silicide layer 108 has a smaller work function than the metal layer 106. In the context of this example, it is preferable that the semiconductor layer 104 be doped with one or more N-type impurities. As a result, N-type impurities are accumulated in the impurity accumulation layer 110.

When the metal silicide layer 108 has a smaller work function than the metal layer 106, the metal layer 106 may be formed from one or more materials selected from the group consisting of cobalt, nickel, platinum, and palladium. Accordingly, the metal silicide layer 108 may be formed from one or more materials selected from the group consisting of cobalt silicide, nickel silicide, platinum silicide, and palladium silicide. Furthermore, the metal silicide layer 108 may be formed from one or more materials selected from a group consisting of cobalt germanosilicide, nickel germanosilicide, platinum germanosilicide, and palladium germanosilicide.

Hereinafter, one exemplary method of forming a semiconductor having a dual gate according to another embodiment will be described. That is, in a forming method according to another embodiment, the first region “a” is the PMOS region and the second region “b” is the NMOS region. In this case, the metal silicide layer 108 has a larger work function than the metal layer 106. In the context of this embodiment, it is preferable that the semiconductor layer 106 be doped with P-type impurities. Accordingly, P-type impurities are accumulated in the impurity accumulation layer 110.

When the metal silicide layer 108 has a larger work function than the metal layer 106, the metal layer 106 may be formed from one or more materials selected from the group consisting of molybdenum, tungsten, zirconium, and tantalum. Accordingly, the metal silicide layer 108 may be formed from one or materials selected from the group consisting of molybdenum silicide, tungsten silicide, zirconium silicide, and tantalum silicide. Furthermore, the metal silicide layer 108 may be formed from one or more materials selected from the group consisting of molybdenum germanosilicide, tungsten germanosilicide, zirconium germanosilicide, and tantalum germanosilicide.

The deposition process used to form the metal layer 106 and the silicidation process may then be sequentially performed. On the contrary, the depositing process for the metal layer 106 and the silicidation process may be performed in-situ. That is, an inside temperature for a conventional process chamber (not shown) used to deposit the metal layer 106 and the temperature of a chuck holding the subject semiconductor wafer are controlled to be substantially similar to that of the temperature required by the silicidation process in order to perform the deposition process for the metal layer 106 and the silicidation process in-situ.

A capping conductivity layer 112 may be formed on the metal silicidation layer 108 of the first region “a” and the metal layer 106 of the second region “b”. The capping conductivity layer 112 may be made formed from a conductive material which is easily etched compared to the metal layer 106. Also, the capping conductivity layer 112 may be formed from a conductive material having lower resistance than the metal silicide layer 108. For example, the capping conductivity layer 112 may be formed from doped polysilicon, a metal such as tungsten and molybdenum, or a conductive metal nitride such as titanium nitride and tantalum nitride.

A hard mask layer 114 may be formed on the capping conductivity layer 112. The hard mask layer 114 may be made of silicon oxide, silicon oxy-nitride or silicon nitride.

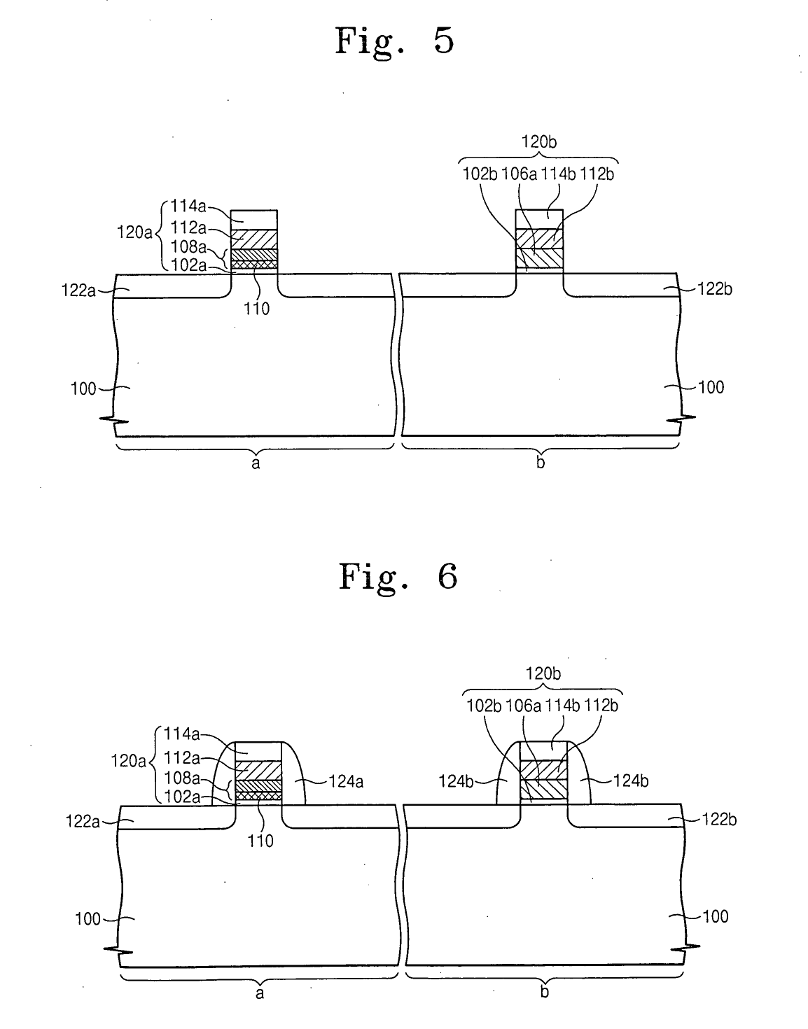

Referring to FIG. 5, a first gate pattern 120a is formed using patterning process and the hard mask layer 114 within the first region “a”, to form the capping conductivity layer 112, the metal silicide layer 108 and the insulating layer 102. The first gate pattern 120a comprises a first gate insulating layer 102a, a first gate electrode 108a, a first capping conductivity pattern 112a and a first mask pattern 114a. The first gate insulating layer 102a is a portion of the insulating layer 102, and the first gate electrode 108a is a portion of the metal silicide layer 108. An impurity accumulation layer 110 may be provided at a lower portion of the first gate electrode 108a. After forming the first gate pattern 120a, a portion of the insulating layer 102 may remain on both sides of the first gate pattern 120a of the semiconductor substrate 100.

A second gate pattern 120b is similarly formed using a conventional patterning process and the hard mask layer 114, to form the capping conductivity layer 112, the metal layer 106 and the insulating layer 102 on the second region “b”. The second gate pattern 120b comprises a second gate insulating layer 102b, a second gate electrode 106a, a second capping conductivity pattern 112b and a second mask pattern 114b. The second gate insulating layer 102b is a portion of the insulating layer 102 and the second gate electrode 106a is a portion of the metal layer 106. After forming the second gate pattern 120b, a portion of the insulating layer 102 may remain on both sides of the second gate pattern 120b of the semiconductor substrate 100.

In one embodiment, it is preferable to form the first gate pattern 120a and the second gate pattern 120b at the same time. Alternatively, the first gate pattern 120a and the second gate pattern 120b may be formed in sequence.

During the patterning process used to form the gate patterns 120a, 120b, the metal layer 106 may be formed to have thickness as thin as about 10 angstroms to about 100 angstroms in order to easily etch the metal layer 106. Also, the semiconductor layer 104 may be formed to be thin in order to properly satisfy the silicon requirement for the metal silicide layer 108. In this case, the capping conductivity layer 112 may be formed to satisfy a thickness requirement for the gate patterns 120a, 120b. Where such is the case, it is preferable to form the capping conductivity layer 112 from a conductive material that may be easily etched. Additionally, the capping conductivity layer 112, when used, protects the metal silicide layer 108 and the metal layer 106, and may have a lower resistance than the metal silicide layer 108.

However, the capping conductivity layer 112 may be omitted. When the capping conductivity layer 112 is not formed, the metal layer 106 is formed to have a sufficient thickness to satisfy a required thickness of the second gate pattern 120b. The semiconductor layer 105 is also formed to be thicker than is necessary to satisfy an amount of silicon required by the metal silicide layer 108.

Referring to FIG. 5, a first conductivity type impurity is selectively ion-implanted in the semiconductor substrate 100 of the first region “a” using the first gate pattern 120a as a mask. Accordingly, a first low-concentration doping layer 122a is formed at both sides of the first gate pattern 120a in the semiconductor substrate 100 of the first region “a”. It is preferable to dope the semiconductor substrate 100 of the first region “a” with second conductivity type impurities. Before forming the insulating layer 102 in FIG. 2 on the semiconductor substrate 100 of the first region “a”, a well doped with second conductivity type impurities.

Using the second gate pattern 120b as a mask, second conductivity impurities are selectively ion-implanted in the semiconductor substrate 100 of the second region “b”. As a result, a second low-concentration doping layer 122b is formed on both sides of the second gate pattern 120b of the semiconductor substrate 100. It is preferable to dope the second region “b” with first conductivity type impurities. Before forming the insulating layer 102 on the semiconductor substrate 100 of the second region “b”, a well doped with first conductivity type impurities may be formed.

In one embodiment, it is preferable that the impurities in the impurity accumulation layer 100 comprise impurities similar to the first low-concentration doping layer 122a.

Referring to FIG. 6, a first spacer 124a may be formed on side walls of the first gate patterns 120a, and a second spacer 124b is formed on side walls of the second gate pattern 120b. The first spacer 124a and the second spacer 124b may be formed simultaneously. The first spacer 124a and the second spacer 124b may be made formed from a material selected from a group consisting of silicon oxide, silicon oxy-nitride, and silicon nitride, and/or any reasonable combination thereof.

Using the first spacer 124a and the first gate pattern 120a as a mask, first conductivity type impurities are selectively ion-implanted at the semiconductor substrate 100 of the first region “a”. As a result, a first high-concentration doping layer 126a is formed as shown in FIG. 1. The first low-concentration doping layer 122a and the first high-concentration doping layer 126a form a first source/drain region 128a.

Using the second spacer 124b and the second gate pattern 120b as a mask, second conductivity type impurities are selectively ion-implanted at the semiconductor substrate 100 in the second region “b”. As a result, a second high-concentration doping layer 126b is formed as shown in FIG. 2. The second low-concentration doping layer 122b and the second high-concentration doping layer 126b form a second source/drain region 128b.

The first source/drain region 128a and the second source/drain region 128b may have a lightly doped drain (LDD) structure or an extended source/drain structure. Or, the source/drain regions 128a and 128b may include only the first low-concentration doping layer 122a or the second low-concentration doping layer 122b, respectively.

As described above, the exemplary method according to one embodiment of the invention may be used to form a semiconductor device having a dual gate electrode, as shown for example in FIG. 1.

As described above, one of the NMOS gate electrode and the PMOS gate electrode is the first gate electrode made of the metal silicide layer, and the other is the second gate electrode made of the metal layer. The first gate electrode and the second gate electrode have different work functions. Accordingly, both the NMOS gate electrode and the PMOS gate electrode have improved work functions. Therefore, the NMOS transistor and the PMOS transistor may be operated at higher speeds since both of the NMOS transistor and the PMOS transistor have improved threshold voltages.

Furthermore, the impurity accumulation layer, which includes N-type impurities or P-type impurities, is disposed at the lower portion of the first gate electrode. The impurity accumulation layer controls the work function of the first gate electrode. Therefore, the work function of the transistor having the first gate electrode may be further improved.

It will be apparent to those skilled of ordinary skill in the art that various modifications and variations may be made to the foregoing embodiments. It is intended that the scope of the invention, as defined by the following claims, will cover all such modifications and variations and their equivalents.

What is claimed is:

1. A semiconductor device comprising:
a first gate electrode formed on a first region of a semiconductor substrate and comprising a metal silicide formed from a metal; and,
a second gate electrode formed on a second region of the semiconductor substrate and comprising the metal.

2. The semiconductor device of claim 1, wherein the first gate electrode comprises:
an impurity accumulation layer formed at a lower portion of the first gate electrode.

3. The semiconductor device of claim 2, further comprising:
a gate insulating layer formed between the first gate electrode and the first region;
a first source/drain region of first conductivity type formed in the semiconductor substrate on opposing sides of the first gate electrode;
a gate insulating layer formed between the second gate electrode and the second region; and,
a second source/drain region of second conductivity type formed in the semiconductor substrate on opposing sides of the second gate electrode;
wherein the impurity accumulation layer is of first conductivity type.

4. The semiconductor device of claim 2, wherein the first region is an NMOS transistor region, the second region is a PMOS transistor region, and the first gate electrode has a smaller work function than the second gate electrode.

5. The semiconductor device of claim 4, wherein impurities in the impurity accumulation layer are one or more N-type impurities.

6. The semiconductor device of claim 4, wherein the metal comprises at least one selected from a group consisting of cobalt, nickel, platinum, and palladium.

7. The semiconductor device of claim 2, wherein the first region is a PMOS region, the second region is an NMOS region, and the first gate electrode has a larger work function than the second gate electrode.

8. The semiconductor device of claim 7, wherein impurities in the impurity accumulation layer are one or more P-type impurities.

9. The semiconductor device of claim 7, wherein the first gate electrode and the second gate electrode each comprise at least one selected from the group consisting of molybdenum, tungsten, zirconium, and tantalum.

10. The semiconductor device of claim 1, further comprising:
a first capping conductivity pattern formed on the first gate electrode; and
a second capping conductivity pattern formed on the second gate electrode.

11. A method of forming a semiconductor device, comprising:
forming an insulating layer on a semiconductor substrate and forming a semiconductor layer on the insulating layer, wherein the semiconductor substrate comprises first and second regions;
exposing a portion of the insulating layer by removing a portion of the semiconductor layer on the second region;
after exposing the portion of the insulating layer, depositing a metal layer on the first and second regions of the semiconductor substrate;
forming a metal silicide layer from a remaining portion of the semiconductor layer and a portion of the metal layer formed on the first region using a silicidation process;
forming a first gate electrode from the metal silicide layer on the first region; and
forming a second gate electrode from the metal layer on the second region.

12. The method of claim 11, wherein the semiconductor layer is doped with impurities, and wherein the silicidation process further comprises:
forming an impurity accumulation layer at a lower portion of the metal silicide layer.

13. The method of claim 12, further comprising:
forming a first source/drain region of first conductivity type in the semiconductor substrate on opposing sides on the first gate electrode; and
forming a second source/drain region of second conductivity type in the semiconductor substrate on opposing sides of the second gate electrode;
wherein the impurity accumulation layer is of first conductivity type.

14. The method of claim 12, wherein the first region is an NMOS region, the second region is a PMOS region, and the metal silicide layer has a smaller work function than the metal layer.

15. The method of claim 14, wherein impurities in the impurity accumulation layer are one or more N-type impurities.

16. The method of claim 14, wherein the metal layer comprises one or more selected from a group consisting of cobalt, nickel, platinum, and palladium.

17. The method of claim 12, wherein the first region is a PMOS region, the second region is an NMOS region, and the metal silicide layer has a larger work function than the metal layer.

18. The method of claim 17, wherein impurities in the impurity accumulation layer are one or more P-type impurities.

19. The method of claim 17, wherein the metal layer comprises one or more selected from a group consisting of molybdenum, tungsten, zirconium, and tantalum.

20. The method of claim 13, further comprising:
forming a capping conductivity layer on the first and second regions of the semiconductor substrate, and,
wherein the first gate electrode comprises a portion of the metal silicide layer and a first capping conductivity pattern formed from the capping conductivity layer, and
wherein the second gate electrode comprises a portion of the metal layer and a second capping conductivity pattern formed from the capping conductivity layer.

21. The method of claim 11, wherein the semiconductor layer is doped using an in-situ doping process.
